(19) United States
(12) Patent Application Publication
(10) Pub. No.: US 2011/0006837 A1
(43) Pub. Date: Jan. 13, 2011

(54) Graphene Device, Method of Investigating Graphene, and Method of Operating Graphene Device

(76) Inventors: Feng Wang, (US); Yuanbo Zhang, (US); Tsung-ta Tang, (US); Michael F. Crommie, (US); Alexander K. Zettl, (US); Caglar Girit, (US)

Correspondence Address: LAWRENCE BERKELEY NATIONAL LABORATORY, Technology Transfer & Intellectual Propery Managem, One Cyolotron Road MS 56A-120, BERKELEY, CA, 94720, US

(21) Appl. No.: 12/792,647

(22) Filed: Jun. 2, 2010

Related U.S. Application Data
(60) Provisional application No. 61/183,538, filed on Jun. 2, 2009.

(51) Int. Cl. G05F 3/02; H01L 29/66; G01N 21/00

(52) U.S. Cl. 327/539; 257/9; 356/237.1; 257/E29.168

(57) ABSTRACT

The present invention provides for a graphene device comprising: a first gate structure, a second gate structure that is transparent or semi-transparent, and a bilayer graphene coupled to the first and second gate structures, the bilayer graphene situated at least partially between the first and second gate structures. The present invention also provides for a method of investigating semiconductor properties of bilayer graphene and a method of operating the graphene device by producing a bandgap of at least 50 mV within the bilayer graphene by using the graphene device.

### RELATED APPLICATIONS

The application claims priority to U.S. Provisional Patent Application Ser. No. 61/183,538, filed Jun. 2, 2009, which is herein incorporated by reference in its entirety.

### STATEMENT OF GOVERNMENT SUPPORT

This invention was made with government support under Contract No. DE-AC02-05CH11231 awarded by the U.S. Department of Energy. The government has certain rights in this invention.

### BACKGROUND OF THE INVENTION

The present invention relates to the field of graphene and, more particularly, to the field of graphene devices.

The electronic bandgap is an intrinsic property of semiconductors and insulators that largely determines their transport and optical properties. As such, it has a central role in modern device physics and technology and governs the operation of semiconductor devices such as p-n junctions, transistors, photodiodes and lasers (ref. 1). A tunable bandgap would be highly desirable because it would allow great flexibility in design and optimization of such devices, in particular if it could be tuned by applying a variable external electric field. However, in conventional materials, the bandgap is fixed by their crystalline structure, preventing such bandgap control.

Graphene's unique electronic band structure has led to fascinating phenomena, exemplified by massless Dirac fermion physics (refs. 10-12) and an anomalous quantum Hall effect (refs. 13-16). With one more graphene layer added, bilayer graphene has an entirely different (and equally interesting) band structure. Most notably, the inversion symmetric AB-stacked bilayer graphene is a zero-bandgap semiconductor in its pristine form. But a non-zero bandgap can be induced by breaking the inversion symmetric of the two layers. Indeed, a bandgap has been observed in a one-side chemically doped epitaxial graphene bilayer (refs. 6,8).

Of particular importance, however, is the potential of a continuously tunable bandgap through an electrical field applied perpendicularly to the sample (refs. 17-20). Such control has proven elusive. Electrical transport measurements on dual-gated bilayer graphene exhibit insulating behavior only at temperatures below 1 kelvin (ref. 2), suggesting a bandgap value much lower than theoretical predictions (refs. 17,18). Optical studies of bilayers have so far been limited to samples with a single electrical gate (refs. 4,5,9), in which carrier doping effects dominate and obscure the signatures of a gate-induced bandgap. Such lack of experimental evidence has cast doubt on the possibility of achieving gate controlled bandgaps in graphene bilayers (ref. 9).

### SUMMARY OF THE INVENTION

Embodiments of the present invention include a graphene device, a method of investigating semiconductor properties of graphene, and a method of operating a bilayer graphene device. An embodiment of a graphene device of the present invention includes a first gate structure, a second gate structure, and bilayer graphene coupled to the first and second gate structures. The second gate structure is transparent or semi-transparent. The bilayer graphene is situated at least partially between the first and second gate structures.

An embodiment of a method of investigating semiconductor properties of bilayer graphene includes providing a bilayer graphene device. The bilayer graphene device includes a first gate structure, a second gate structure that is transparent or semi-transparent, and bilayer graphene coupled to the first and second gate structures. The bilayer graphene is situated at least partially between the first and second gate structures. The method further includes probing the semiconductor properties of the bilayer graphene device using a light source to illuminate the bilayer graphene at least partially through the second gate structure.

An embodiment of a method of operating a graphene device includes providing a bilayer graphene device. The device includes a first gate structure, a second gate structure, and bilayer graphene coupled to the first and second gate structures. The bilayer graphene is situated at least partially between the first and second gate structures. The method further includes producing a bandgap of at least 50 mV within the bilayer graphene. The bandgap is produced by applying first and second electric fields to the bilayer graphene using the first and second gate structures, respectively.

### BRIEF DESCRIPTION OF THE DRAWINGS

The present invention is described with respect to particular exemplary embodiments thereof and reference is accordingly made to the drawings in which:

FIG. 1: Dual-gated bilayer grapheme. a. Optical microscopy image of the bilayer device (top view). b. Illustration of a cross-sectional side view of the gated device. c. Sketch showing how gating of the bilayer induces top (Dₜ) and bottom electrical displacement fields (D_{b}). d. Left: Electronic structure of a pristine bilayer has zero bandgap. Right: Upon gating, the displacement fields induces a non-zero bandgap (Δ) and a shift of the Fermi energy (E_{F}). e. Graphene electrical resistance as a function of top gate voltage (Vₜ) at different fixed bottom gate voltages (V_{b}). The traces are taken with a 20 V steps in V_{b} from 60 V to −100 V and at V_{b}=−130 V. The resistance peak in each curve corresponds to the CNP (δD=0) for a given bottom gate voltage. f. The linear relation between top and bottom gate voltages that results in bilayer CNPs.

FIG. 2: Bilayer energy gap opening at strong electrical gating. a. Allowed optical transitions between different subbands of a graphene bilayer. Curves are offset from zero for clarity. b. Gate-induced absorption spectra at CNP for different applied displacement fields D̅ (with spectrum for zero-bandgap CNP subtracted as reference). For clarity, the traces were displaced by 2%, 4%, 6% and 8%, respectively. Absorption peaks due to transitions I at gate-induced bandgaps are apparent (dashed black lines are guides to the eye). At the same time, a reduction of absorption below the bandgap is expected. This reduction is clearly observed in the trace with the largest bandgap (Δ=250 meV) in our experimental spectral range. The sharp asymmetric resonance observed near 200 meV is due to Fano resonance of the zone center G-mode phonon with the continuum electronic transitions. The broad feature around 400 meV is due to electronic transitions II, III, IV and V. c. Theoretical prediction of the gate-induced absorption spectra based on a tight-binding model where the bandgap value is taken as an adjustable parameter. The fit provides an accurate determination of the gate-tunable bandgap at strong electrical gating.

FIG. 3: Bilayer energy gap opening at weak electrical gating. a. Absorption difference between electron doped (δD=0.15 V/nm) and charge neutral bilayer (δD=0) at different average displacement fields D̅. The curves are displaced by multiples of 0.5% for clarity. The absorption peak is mainly due to increased absorption between nearly parallel conduction bands from extra filled initial states (transition IV in FIG. 2a). This absorption peak shifts to lower energy due to the opening of the bilayer bandgap with increasing D̅. b. Calculated absorption difference spectra based on a tight binding model using the gate-induced bandgap as an adjustable parameter. Good agreement between theory and experiment on the absorption peak redshift (black dashed lines in FIGS. 2a and 2b) yields the gate induced bilayer bandgap at weak gating.

FIG. 4: Electric-Field dependence of tunable energy bandgap in graphene bilayer. Experimental data (red dots) are compared to theoretical predictions based on self-consistent tight-binding (black trace), ab inito density functional (red trace), and unscreened tight-binding calculations (blue dashed trace). Error bar is estimated from the uncertainty in determining the absorption peaks in the spectra.

FIG. 5: Doping effect at high electric displacement field. a. Absorption difference between electron doped (δD=0.15 V/nm) and charge neutral bilayer (δD=0) at high displacement fields D̅. b. Calculated absorption difference spectra based on a tight binding model using the gate-induced bandgap (Δ) as an adjustable parameter. Both experiment and theory show a broadening of the absorption peak and the appearance of reduced low energy absorption at the highest displacement field. Such low energy absorption reduction is due to the Pauli blocking of bandgap transitions.

FIG. 6 illustrates an embodiment of graphene device of the present invention.

### DETAILED DESCRIPTION OF THE INVENTION

Embodiments of the present invention include a graphene device, a method of investigating semiconductor properties of bilayer graphene, and a method of operating a bilayer graphene device.

An embodiment of a bilayer graphene device of the present invention is illustrated in FIG. 6. The graphene device 100 includes a first gate structure 102, a second gate structure 104, and bilayer graphene 106. In an embodiment of the bilayer graphene device 100, the first gate structure 102 forms a substrate upon which the bilayer graphene device 100 is fabricated. The first gate structure 102 includes a first conducting layer 108 (i.e. a first gate) and a first insulating layer 110. For example, the first conducting layer 108 may be heavily doped silicon and the insulating layer 110 may be silicon dioxide. The second gate structure 104 is transparent or semi-transparent. For example, the second gate structure 104 may be transparent or semi-transparent within an infrared portion of the electromagnetic spectrum (i.e. an infrared regime). The second gate structure 104 includes a second conducting layer 112 (i.e. a second gate) and a second insulating layer 114. For example, the second conducting layer 112 may be Pt and the second insulating layer 114 may be Al₂O₃. The graphene device 100 may further include first and second electrodes, 116 and 118, (e.g., a source and a drain) that contact the bilayer graphene.

An embodiment of a method of investigating semiconductor properties of graphene includes providing a graphene device 100. The semiconductor properties of the graphene are probed using a light source to illuminate the bilayer graphene 106 at least partially through the second gate structure 104. For example, the light source may be a broad spectrum light source, a light emitting diode, a laser, or a synchrotron. In an embodiment, the light source emits light at least partially within the infrared portion of the electromagnetic spectrum.

An embodiment of a method of operating a graphene device includes providing the graphene device. The graphene device includes bilayer graphene that is situated at least partially between first and second gate structures. While the second gate structure of this graphene device may be transparent or semi-transparent as in the graphene device 100, it could be opaque (i.e. not transparent or semitransparent). The method further includes producing a bandgap within the bilayer graphene by applying first and second electric fields using the first and second gate structures, respectively. In an embodiment, the bandgap that is produced is a bandgap of at least 50 mV. In another embodiment, the bandgap that is produced is a bandgap of at least 100 mV. In yet another embodiment, the bandgap that is produced is a bandgap of at least 150 mV.

In an embodiment, the method of operating the graphene device further includes adjusting the bandgap by changing at least one of the first and second electric fields produced by the first and second gate structures, respectively. In another embodiment, the method of operating the graphene device further includes introducing carriers by changing at least one of the first and second electric fields produced by the first and second gate structures, respectively. The carriers may be holes or electrons. This embodiment may further include maintaining a constant bandgap while introducing the carriers. In yet another embodiment, the method of operating the graphene device further includes detecting a response within the bilayer graphene due to an incident photon or photons. For example, the graphene device may be used as a photon or light detector. In another embodiment, the method of operating the graphene device further includes injecting holes and electrons into the bilayer graphene between the first and second electrodes to produce a photon or photons. For example, the graphene device may be used as a light source. In another embodiment, the bilayer graphene is at least partially suspended between the first and second gate structures.

Discussion:

Here we demonstrate the realization of a widely tunable electronic bandgap in electrically gated bilayer graphene. Using a dual-gate bilayer graphene field-effect transistor (FET) and infrared microspectroscopy (refs. 3-5), we demonstrate a gate-controlled, continuously tunable bandgap of up to 250 meV. Our technique avoids uncontrolled chemical doping (refs. 6-8) and provides direct evidence of a widely tunable bandgap—spanning a spectral range from zero to mid-infrared—that has eluded previous attempts (refs. 2,9). Combined with the remarkable electrical transport properties of such systems, this electrostatic bandgap control suggests novel nanoelectronic and nanophotonic device applications based on graphene.

Here, we use novel dual-gate graphene FETs to demonstrate unambiguously a widely field-tunable bandgap in bilayer graphene with infrared absorption spectroscopy. By using both top and bottom gates in the graphene FET device we are able to control independently the two key semiconductor parameters: electronic bandgap and carrier doping concentration.

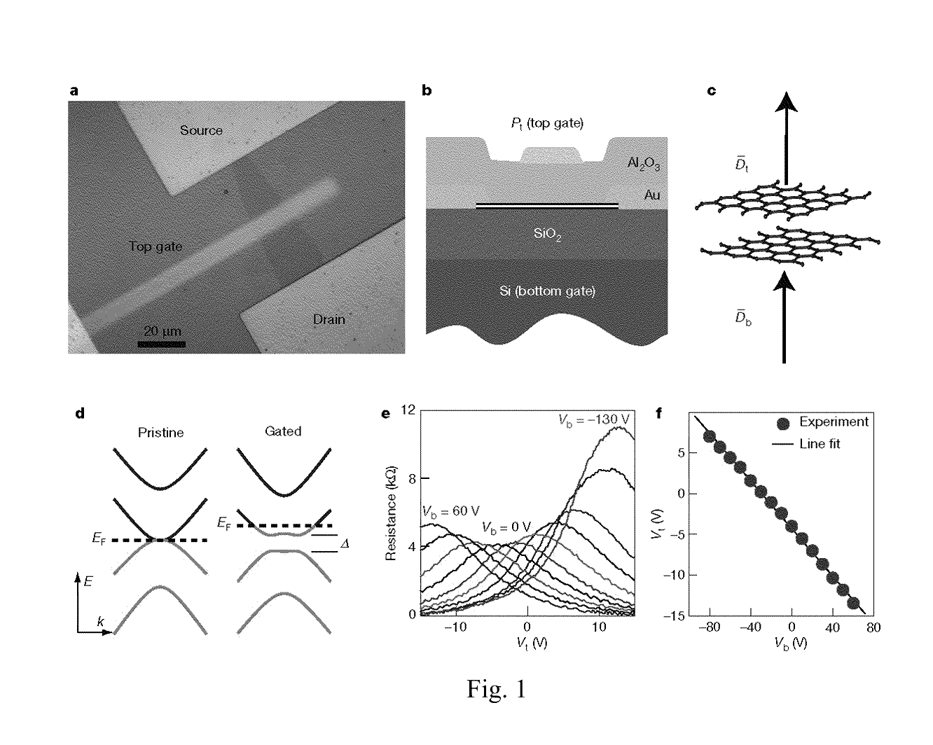

The electronic structure near the Fermi level of an AB-stacked graphene bilayer features two nearly parallel conduction bands above two nearly parallel valence bands (FIG. 1d) (ref. 21). In the absence of gating, the lowest conduction band and highest valence band touch each other with a zero bandgap. Upon electrical gating, the top and bottom electrical displacement fields Dₜ and D_{b} (FIG. 1c) produce two effects (FIG. 1d): The difference of the two, δD=D_{b}−Dₜ, leads to a net carrier doping, that is, a shift of the Fermi energy (E_{F}). The average of the two, D̅=(D_{b}+Dₜ)/2, breaks the inversion symmetry of the bilayer and generates a non-zero bandgap Δ (refs. 7,17,18). By setting δD to zero and varying D̅, we can tune the bandgap while keeping the bilayer charge neutral. Sets of D_{b} and Dₜ leading to δD=0 define the bilayer ‘charge neutral points’ (CNPs). By varying δD above or below zero, we can inject electrons or holes into the bilayer and shift the Fermi level without changing the bandgap. In our experiment the drain electrode is grounded and the displacement fields Dₜ and D_{b} are tuned independently by top and bottom gate voltages (Vₜ and V_{b}) through the relations D_{b}=+∈_{b}(V_{b}−V_{b}⁰)/d_{b} and Dₜ=−∈ₜ(Vₜ−Vₜ⁰)/dₜ. Here ∈ and dare the dielectric constant and thickness of the dielectric layer and V⁰ is the effective offset voltage due to initial environment induced carrier doping.

The relationship between D and V for the top or bottom layers can be determined through electrical transport measurement (ref. 2). FIG. 1e shows the measured resistance along the graphene plane as a function of Vₜ with V_{b} fixed at different values, and CNPs can be identified by the peaks in the resistance curves, because charge neutrality results in a maximum resistance. The deduced CNPs, in terms of (Vₜ,V_{b}), are plotted in FIG. 1f. Vₜ and V_{b} are linearly related with a slope of about 0.15, consistent with the expected value of −(∈_{b}dₜ/∈ₜd_{b}), where d_{b}=285 nm, ∈_{b}=3.9 for thermal SiO₂, and dₜ=80 nm, ∈ₜ=7.5 for amorphous Al₂O₃. The peak resistance differs at different CNPs (FIG. 1e) because the field-induced bandgap itself differs. Lower peak resistance comes from a smaller bandgap. Thus, the lowest peak resistance allows us roughly to identify the zero-bandgap CNP (D_{b}=Dₜ=0) and determine the offset top and bottom gate voltages from environment doping to be Vₜ⁰≈−5 V and V_{b}⁰≈10 V. With the values of ∈/d and gate voltage offsets, the displacement electric field can be determined within an uncertainty of about 10%. We note that although CNP resistance data shows an increase with the field-induced bandgap, the increase is much smaller than expected for a large energy gap opening. This is attributed to extrinsic conduction through defects and carrier doping from charge impurities in our samples.

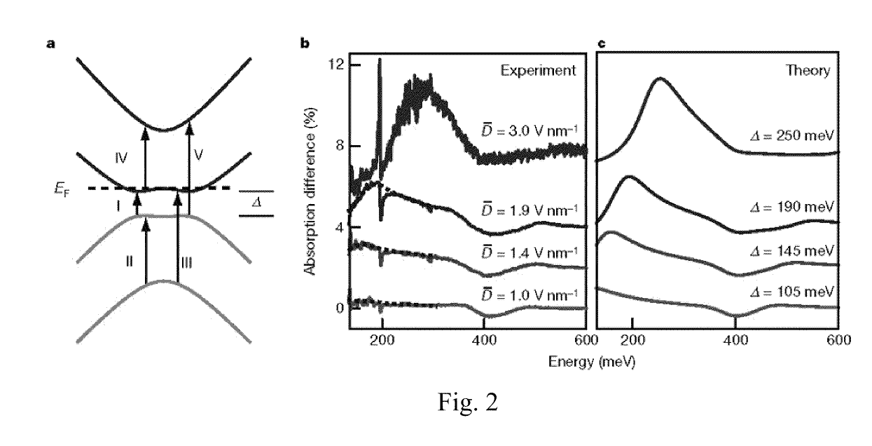

To determine the true bilayer bandgap reliably, we used infrared microspectroscopy (refs. 3,4) (FIG. 2a). Such an optical determination electronic bandgap is generally less affected by defects or doping than electrical transport measurements (ref. 2). FIG. 2b shows the gate-induced bilayer absorption spectra at CNPs (δD=0) with D̅=1.0V nm⁻¹, 1.4 V nm⁻¹, 1.9 V nm⁻¹ and 3.0 V nm⁻¹. The absorption spectrum of the sample at the zero-bandgap CNP ( D̅=0) has been subtracted as a background reference to eliminate contributions to the absorption from the substrate and gate materials. Two distinct features are present in the spectra, a gate-dependent peak below 300 meV and a dip centered around 400 meV. These arise from different optical transitions between the bilayer electronic bands, as illustrated in FIG. 2a. Transition I is the tunable bandgap transition that accounts for the gate-induced spectral response at energies lower than 300 meV. Transitions II, III, IV and V occur at and above the energy of parallel band separation (γ≡400 meV) and contribute to the spectral feature near 400 meV.

The absorption peak below 300 meV in FIG. 2b shows pronounced gate tunability: it gets stronger and shifts to higher energy with increasing D̅. This arises because as the bandgap increases, so does the density of states at the band edge. The peak position, corresponding to the bandgap, increases from 150 meV at D̅=1.4 V nm⁻¹ to 250 meV at D̅=3 V nm⁻¹. This shows directly that the bandgap can be continuously tuned up to at least 250 meV by electrical gating. The bandgap transitions are remarkably strong: optical absorption can reach 5% in two atom layers, corresponding to an oscillator strength that is among the highest of all known materials. On the basis of the sum rule, a reduction of absorption below the bandgap should accompany the prominent band-edge absorption peak. This absorption reduction is clearly observed in the trace with the largest bandgap (Δ=250 meV) in our experimental spectral range. We also notice in FIG. 2b a very sharp spectral feature at 1,585 cm⁻¹ (about 200 meV). This narrow resonance can be attributed to the zone-centre G-mode phonon in graphene (ref. 22). The asymmetric line shape originates from Fano interference between the discrete phonon and continuous electronic (bandgap) transitions.

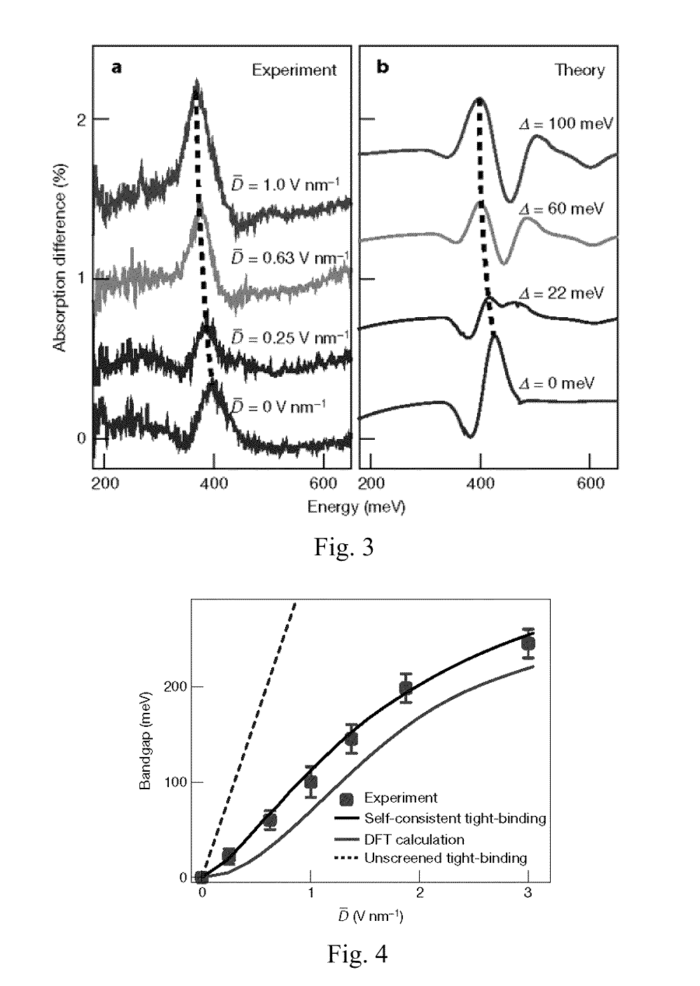

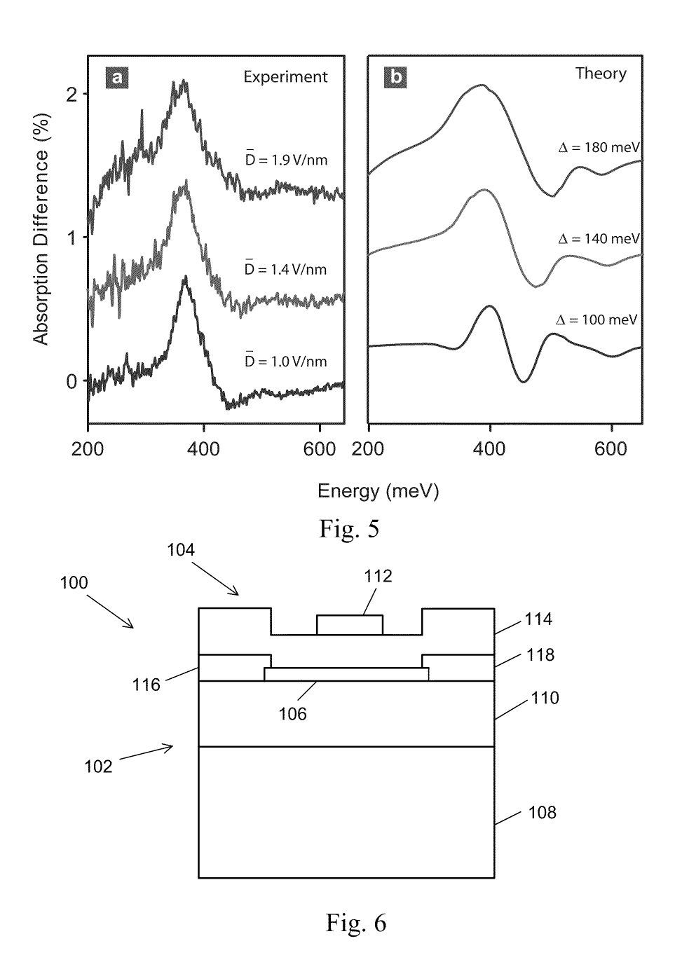

When the displacement field D̅ is weak (<1.2 V nm⁻¹), the gate induced bandgap becomes too small to be measured directly. However, it can still be extracted from spectral changes around 400 meV induced by electron doping through gating. This is achieved by measuring the difference in bilayer absorption for δD=0 (CNP) and δD=1.5 V nm⁻¹ (electron-doped) at different fixed D̅ values (FIG. 3a). We first examine the optical transitions in FIG. 2a, to understand the bilayer absorption difference due to electron doping. With electrons occupying the conduction band states, transition IV becomes stronger from extra filled initial states and transition III becomes weaker because of fewer available empty final states. However, transition IV is more prominent and gives rise to the observed peaks in the absorption difference spectra because all such transitions have similar energy owing to the nearly parallel conduction bands. When the bandgap increases with increasing D̅, the lower conduction band moves up, but the upper conduction band hardly changes, making the separation between the two bands smaller. This will lead to a redshift of transition IV. Therefore, the shift of the peak in the difference spectrum can yields the bilayer bandgap when compared to theory. When the gate-induced bandgap is small, this shift equals roughly half of the bandgap energy. At higher D̅ values, deviation from the near-parallel band picture becomes significant and a broadening of the absorption peak takes place as shown in FIG. 5. We obtained quantitative understanding of the gate-induced bandgap and its associated optical properties through comparison of our data to theoretical predictions. We modeled the bilayer absorption using the self-consistent tight-binding model following ref. 23, except that the bandgap was treated as a fitting parameter here. We have included a room-temperature thermal broadening of 25 meV and an extra inhomogeneous broadening of 60 meV to account for sample inhomogeneity. We note that this large inhomogeneous broadening is comparable to that estimated from transport studies (ref. 24) and it accounts for the difficulty in electrical determination of the bilayer graphene bandgap. FIG. 2c shows our calculated gate induced absorption spectra and bandgaps of bilayer graphene extracted by matching the absorption peak between 130-300 meV in the ‘large bandgap’ regime (Δ>120 meV). Agreement with the experimental spectra (FIG. 2b) is excellent, except for the phonon contribution at ˜200 meV, which is not included in our model. For the ‘small bandgap’ regime (Δ<120 meV), we are able to determine the bilayer bandgap by comparing our model calculations to the measured absorption difference spectra shown in FIG. 3a. Our calculations (FIG. 3b) provide a good qualitative fit to the absorption peak that arises from electron transition IV: this absorption peak shifts to lower energy as the bandgap becomes larger, reproducing the observed behavior at increasing displacement field D̅ in FIG. 3a. By matching the experimental and theoretical values of this absorption peak shift, we can extract the bilayer bandgap at different D̅ in the ‘small bandgap’ regime.

FIG. 4 shows a plot of the experimentally derived gate-tunable bilayer bandgap over the entire range (0<Δ<250 meV) as a function of applied displacement field D̅ (data points). Our experimental bandgap results are compared to predictions based on self-consistent tight-binding calculations (black trace) (ref. 23), ab initio density functional (red trace) (ref. 18), and unscreened tight-binding calculations (dashed blue line) (ref. 7). Clearly the inclusion of graphene self-screening is crucial in achieving good agreement with the experimental data, as in the self consistent tight-binding and ab initio calculations. The ab initio calculation predicts a slightly smaller bandgap than does the tight binding model. This is partly owing to the different values used for onsite interlayer coupling γ₁, which is 0.4 eV for the tight binding and 0.34 eV for the ab initio calculations. Similar underestimation of bandgaps by ab initio local density functional calculations is common for semiconductors (ref. 25).

Our study shows a confluence of interesting electronic and optical properties in graphene bilayer FETs, which provide appealing opportunities for new scientific exploration and technological innovation. The achieved gate-tunable bandgap (250 meV), an order of magnitude higher than the room-temperature thermal energy (25 meV), emphasizes the intrinsic potential of bilayer graphene for nanoelectronics. With the tunable bandgap reaching the infrared range, and with the unusually strong oscillator strength for the bandgap transitions, bilayer graphene may enable novel nanophotonic devices for infrared light generation, amplification and detection.

Methods Summary

Graphene bilayer flakes were exfoliated from graphite and deposited onto Si/SiO2 wafers as described in ref. 26. Bilayers were identified by optical contrast in a microscope and subsequently confirmed via Raman spectroscopy (ref. 22). Source and drain electrodes (Au, thickness 30 nm) for transport measurement were deposited directly onto the graphene bilayer through a stencil mask under vacuum. The doped Si substrate under a 285-nm-thick SiO₂ layer was used as the bottom gate. The top gate was formed by sequential deposition of an 80-nm-thick Al₂O₃ film and a sputtered strip of 20-nm-thick Pt film. The Pt electrode was electrically conductive and optically semi-transparent. Two-terminal electrical measurements were used for transport characterization. We extracted a carrier mobility of, 1,000 cm² V⁻¹ s⁻¹ from the electrical transport measurements. Infrared transmission spectra of the dual-gated bilayer were obtained using the synchrotron based infrared source from the Advanced Light Source at Lawrence Berkeley National Lab and a micro-Fourier transform infrared spectrometer. All measurements were performed at room temperature (293K).

### REFERENCES

1. Sze, S. M. & Ng, K. K. Physics of Semiconductor Devices (Wiley-Interscience, 2006).
2. Oostinga, J. B., Heersche, H. B., Liu, X. L., Morpurgo, A. F. & Vandersypen, L. M. K. Gate-induced insulating state in bilayer graphene devices. Nature Mater. 7, 151-157 (2008).
3. Li, Z. Q. et al. Dirac charge dynamics in graphene by infrared spectroscopy. Nature Phys. 4, 532-535 (2008).
4. Wang, F. et al. Gate-variable optical transitions in graphene. Science 320, 206-209 (2008).
5. Li, Z. Q. et al. Band structure asymmetry of bilayer graphene revealed by infrared spectroscopy. Phys. Rev. Lett. 102, 037403 (2009).
6. Ohta, T., Bostwick, A., Seyller, T., Horn, K. & Rotenberg, E. Controlling the electronic structure of bilayer graphene. Science 313, 951-954 (2006).
7. Castro, E. V. et al. Biased bilayer graphene: semiconductor with a gap tunable by the electric field effect. Phys. Rev. Lett. 99, 216802 (2007).
8. Zhou, S. Y. et al. Substrate-induced bandgap opening in epitaxial graphene. Nature Mater. 6, 770-775 (2007).
9. Kuzmenko, A. B. et al. Infrared spectroscopy of electronic bands in bilayer graphene. Preprint at, http://arxiv.org/abs/0810.2400. (2008).
10. Geim, A. K. & Novoselov, K. S. The rise of graphene. Nature Mater. 6, 183-191 (2007).
11. Katsnelson, M. I., Novoselov, K. S. & Geim, A. K. Chiral tunneling and the Klein paradox in graphene. Nature Phys. 2, 620-625 (2006).
12. Huard, B. et al. Transport measurements across a tunable potential barrier in graphene. Phys. Rev. Lett. 98, 236803 (2007).
13. Novoselov, K. S. et al. Two-dimensional gas of massless Dirac fermions in graphene. Nature 438, 197-200 (2005).
14. Zhang, Y. B., Tan, Y. W., Stormer, H. L. & Kim, P. Experimental observation of the quantum Hall effect and Berry's phase in graphene. Nature 438, 201-204 (2005).
15. Novoselov, K. S. et al. Unconventional quantum Hall effect and Berry's phase of 2 pi in bilayer graphene. Nature Phys. 2, 177-180 (2006).
16. McCann, E. & Fal'ko, V. I. Landau-level degeneracy and quantum hall effect in a graphite bilayer. Phys. Rev. Lett. 96, 086805 (2006).
17. McCann, E. Asymmetry gap in the electronic band structure of bilayer graphene. Phys. Rev. B 74, 161403 (2006).
18. Min, H. K., Sahu, B., Banerjee, S. K. & MacDonald, A. H. Ab initio theory of gate induced gaps in graphene bilayers. Phys. Rev. B 75, 155115 (2007).
19. Lu, C. L., Chang, C. P., Huang, Y. C., Chen, R. B. & Lin, M. L. Influence of an electric field on the optical properties of few-layer graphene with AB stacking. Phys. Rev. B 73, 144427 (2006).
20. Guinea, F., Neto, A. H. C. & Peres, N. M. R. Electronic states and Landau levels in graphene stacks. Phys. Rev. B 73, 245426 (2006).
21. Abergel, D. S. L. & Fal'ko, V. I. Optical and magneto-optical far-infrared properties of bilayer graphene. Phys. Rev. B 75, 155430 (2007).
22. Ferrari, A. C. et al. Raman spectrum of graphene and graphene layers. Phys. Rev. Lett. 97, 187401 (2006).
23. Zhang, L. M. et al. Determination of the electronic structure of bilayer graphene from infrared spectroscopy. Phys. Rev. B 78, 235408 (2008).
24. Adam, S. & Sarma, S. D. Boltzmann transport and residual conductivity in bilayer graphene. Phys. Rev. B 77, 115436 (2007).
25. Hybertsen, M. S. & Louie, S. G. Electron correlation in semiconductors and insulators—band-gaps and quasi-particle energies. Phys. Rev. B 34, 5390-5413 (1986).
26. Novoselov, K. S. et al. Two-dimensional atomic crystals. Proc. Natl. Acad. Sci. USA 102, 10451-10453 (2005).

As used herein and in the appended claims, the singular forms “a”, “and”, and “the” include plural referents unless the context clearly dictates otherwise.

The foregoing detailed description of the present invention is provided for the purposes of illustration and is not intended to be exhaustive or to limit the invention to the embodiments disclosed. Accordingly, the scope of the present invention is defined by the appended claims.

What is claimed is:

1. A graphene device comprising:
a first gate structure;
a second gate structure that is transparent or semi-transparent; and
a bilayer graphene coupled to the first and second gate structures, the bilayer graphene situated at least partially between the first and second gate structures.

2. The graphene device of claim 1 wherein the second electronic gate structure is transparent or semi-transparent within an infrared regime.

3. The graphene device of claim 1 wherein the second electronic gate structure comprises an insulating layer and an electrode.

4. The graphene electronic device of claim 3 wherein the insulating layer comprises Al₂O₃.

5. The graphene electronic device of claim 3 wherein the electrode comprises Pt.

6. A method of investigating semiconductor properties of bilayer graphene comprising:
providing a bilayer graphene device comprising:
a first gate structure;
a second gate structure that is transparent or semi-transparent; and
bilayer graphene coupled to the first and second gate structures, the bilayer graphene situated at least partially between the first and second gate structures; and
probing the semiconductor properties of the bilayer graphene device using a light source to illuminate the bilayer graphene at least partially through the second gate structure.

7. The method of claim 6 wherein the broad spectrum light source emits at least partially within an infrared regime.

8. The method of claim 6 wherein the lights source is a broad spectrum light source.

9. The method of claim 6 wherein the lights source is a light emitting diode.

10. The method of claim 6 wherein the lights source is a laser.

11. The method of claim 6 wherein the lights source is a synchrotron.

12. A method of operating a graphene device comprising:
providing a bilayer graphene device comprising:
a first gate structure;
a second gate structure; and
bilayer graphene coupled to the first and second gate structures, the bilayer graphene situated at least partially between the first and second gate structures; and
producing a bandgap of at least 50 mV within the bilayer graphene by applying first and second electric fields to the bilayer graphene using the first and second gate structures, respectively.

13. The method of claim 12 wherein producing the bandgap produces a bandgap of at least 100 mV.

14. The method of claim 12 wherein producing the bandgap produces a bandgap of at least 150 mV.

15. The method of claim 12 further comprising adjusting the bandgap by changing at least one of the first and second electric fields produced by the first and second gate structures, respectively.

16. The method of claim 12 further comprising introducing carriers selected from the group consisting of holes and electrons by changing at least one of the first or second electric fields produced by the first and second gate structures, respectively.

17. The method of claim 16 further comprising maintaining a constant bandgap while introducing the carriers.

18. The method of claim 12 further comprising detecting a response within the bilayer graphene due to an incident photon.

19. The method of claim 12 further comprising producing a photon by injecting holes and electrons into the bilayer graphene between the first and second electrodes.

20. The method of claim 12 wherein the bilayer graphene is at least partially suspended between the first and second gate structures.
